(19) United States
(12) Patent Application Publication
(10) Pub. No.: US 2012/0174966 A1
(43) Pub. Date: Jul. 12, 2012

(54) Concentrating tracking solar energy collector

(76) Inventor: Bradford Joel Snipes, LaPorte, TX (US)

(21) Appl. No.: 12/930,506

(22) Filed: Jan. 7, 2011

(51) Int. Cl. H01L 31/058; H01L 31/052; H01L 31/0232

(52) U.S. Cl. 136/248; 136/259; 136/246

(57) ABSTRACT

A Conical reflecting, concentrating, two-axis tracking solar energy collector is disclosed.

An inverted multi-segmented conical reflecting surface concentrates and focuses solar energy at very high concentrations onto a very thermodynamically efficient receiver tube or absorber pipe assembly.

The receiver tube consists of a cylindrical array of HCPV solar cells mounted onto a polygonal extruded Aluminum tube. These HCPV solar cells are 36% efficient and can receive solar concentrations as high as 1000 SUNS. A heat transfer fluid is pumped through the receiver tube in contact with the interior surface of the Aluminum tube to remove the heat from the HCPV solar cells. In cooling the HCPV cells, the heat transfer fluid is heated. The resulting thermal energy, ⅔ of the available solar energy, can be utilized for ammonia absorption air conditioning and home heating, about ⅔-¾ of a home's energy requirement.

The absorber pipe assembly encloses a black surfaced absorber pipe within a larger diameter transparent glass pipe and a heat transfer fluid is pumped through the annulus in direct contact with the black absorbing surface. A very efficient transfer of heat is effected.

This conical concentrator and receiver combination is caused to track the by three hydraulic cylinders.

The concentrating solar energy collector disclose is intended to and is capable of economically providing for all of the energy needs of a home or building.

### BACKGROUND TO THE DISCLOSURE

1. Field of Use

This device relates to the conversion of solar radiation into both electrical and thermal energy.

The objective of this device is to provide for all of the energy requirements of a home, building or community.

2. Prior Art

Relatively low energy densities of available solar radiation at the Earth's surface dictate the use of large areas of solar collection per unit of energy produced.

Many solar collectors available today are proven. However, none of them are economically competitive with conventional utilities which burn fossil fuels for electrical energy production. The solar energy industry has been competing with the artificially low cost of fossil fuels.

Solar collectors which presently predominate the solar home energy market include flat plate thermal energy collectors and flat non-concentrating photovoltaic solar cell arrays.

Both of these designs are relatively inefficient when compared to the present invention.

Photovoltaic solar cell arrays, usually mounted stationary on a home's rooftop, typically have efficiencies between 12% and 14%. This low efficiency necessitates even larger areas of solar collection per unit of energy produced. Also, the cost per unit of area projected to the sun is high because very expensive materials are used.

Flat plate solar thermal energy collectors typically consist of copper sheet with copper tubing thermally bonded to its surface. This copper sheet/copper tubing assembly is usually placed within a insulated box which is covered by a glass cover. A heat transfer fluid is caused to flow through the copper tubing. This fluid receives the thermal energy which results from the absorption of solar radiant energy on the black surface of the copper sheet. The solar radiation received on the blackened surface is converted to thermal energy and then is then transmitted by conduction through the copper sheet to the copper tubing. A large part of the thermal energy collected is lost by radiation and convection from the sheet before it reaches the fluid flowing through the tubes. Only a small fraction of the captured thermal energy is actually absorbed into fluid flowing through the copper tubing. Again, the cost per unit area projected to the sun is high because expensive materials are used. These flat plate collectors cannot deliver temperatures higher than about 160° F. This relegates their use to providing domestic hot water, heating a swimming pool, or similar low temperature applications.

Both of these flat roof-mounted non-concentrating solar energy collectors have increased inefficiencies because the area projected to the sun decreases with increasing solar incidence angles. A maximum area is projected to the sun at noon and the area projected to the sun approaches zero as the sun approaches the horizon. Also solar reflection increases with the increasing incidence angle such that when solar incidence angles increase greater percentages of solar radiation are reflected rather than absorbed.

Neither of these collector types have proven to be economical and therefore have not been truly successful in the marketplace.

Another solar energy collector presently on the market utilizes High Concentration Photovoltaic, HCPV, solar cells to convert solar radiation to electricity. These triple junction HCPV solar cells are much more efficient than the flat non-concentrating solar cell arrays. They have a maximum efficiency of about 38%.

In addition, HCPV solar cells can receive solar concentration ratios as high as 1000 SUNS. Indeed, for their economical use, high solar concentrations are necessary. HCPV solar cells are much more expensive than non-concentrating solar cells. However, when used with solar reflecting concentrators, which can be made of relatively inexpensive material, they can be much more economical than their non-concentrating counterparts.

Typical solar energy systems utilizing the HCPV solar cells have a primary purpose of producing electrical energy to feed into the public utility power grid. Only about 35% of the energy is converted to electricity. The remaining 65% of the available solar energy is converted to thermal energy. Spectrolabs HCPV solar cells have a maximum recommended operating temperature of ˜230° F. The thermal energy, which is about 65% of the solar energy received, must be removed from the cells and some form of cell cooling must be provided. Present HCPV systems typically discard this thermal energy to ambient.

One aspect of thermal energy is that it cannot easily be transported over long distances. Thermal energy should be utilized close to the place where it is produced. Thermal energy can be used for ammonia absorption air conditioning or home heating about ¾'s of a home's energy requirement.

This thermal energy can also be used to provide hot water and distilled water. In the spring and fall months when air conditioning and heating requirements are minimal, surpluses of thermal energy from the collector can be used to heat a swimming pool.

On a larger scale the thermal energy could be used for refrigerating a cold storage warehouse. The 35% of incident solar energy which is converted to electrical energy can be used to make hydrogen.

### SUMMARY OF DISCLOSURE

There are two basic embodiments of the present invention.

Both of these embodiments utilize a inverted truncated conical reflecting surface which concentrates and focuses the sun's rays onto a focal line. Both of these embodiments described utilize hydraulic cylinders to maintain the collectors orientation towards the sun.

It should be noted that other tracking means can also be used.

In one embodiment of the present invention, a cylindrical array of High Concentrating Photovoltaic solar cells, like Spectrolabs CDO-100 CPV Cell, is mounted onto a receiver tube and positioned at the focal line of the conical solar concentrator. A heat transfer fluid flowing through the tube to which the cells are mounted acts to cool the backside of the HCPV solar Cells. In cooling the solar cells the heat transfer fluid absorbs the thermal energy and is heated. This thermal energy can be then be used for a variety of thermal processes.

This differentiates the present invention from existing HCPV systems. The thermal energy is captured and utilized, not discarded to ambient. The economical efficiency of the present invention is greater because almost all of the incoming solar energy is utilized.

The present invention is intended to be utilized as part of a solar home or building energy system which can economically provide for all of the energy requirements of a home, building, or a community. The solar collector described in the following utilizes High Concentration Photovoltaic solar cells and an inexpensive reflecting concentrator to achieve both high thermodynamic efficiency and high economic efficiency.

One objective of the present invention is to convert a maximum amount of usable energy from solar energy at the least possible cost. The present invention accomplishes this in two ways. The overall cost per square foot of solar projected area is very low because the reflecting concentrator is easily fabricated using inexpensive materials. Also because of the inherently high thermodynamic efficiency of the present invention, the area of required solar projection per unit of power produced is greatly reduced.

The electrical energy output of the present invention can provide power for home lighting, appliances, and electronics. This is about 25% of the output of the present invention.

The thermal energy output of the present invention can be used to provide home ammonia absorption air-conditioning and home heating, hot water, distilled water, and swimming pool heating. This is about 75% of the output of the present invention.

It should be noted that the percentages of electrical and thermal energy output of the present invention when used with ammonia absorption air conditioning very closely corresponds to the energy needs of a home.

In one embodiment of this collector Incoming solar radiation is concentrated and focused onto a linear receiver positioned coaxially with a conical reflector in a position to receive the concentrated solar rays. This concentrator-receiver arrangement is caused to track the sun as it moves across the sky by means of three hydraulic cylinders. Several conical segments are used to achieve solar concentrations as high as 1000 SUNS.

This linear receiver consists of a cylindrical array of high concentration photovoltaic cells mounted on the periphery of a flat-sided receiver tube. The sides of a polygonal receiver tube are slightly larger than the width of the HCPV solar cells. Two-sided reflector fins protrude radially outward from each apex of the polygon. This secondary reflector greatly reduces the required fabrication accuracy for the cone.

The HCPV solar cells are flat mounted onto the receiver tube between the apexes of the reflector fins. A good thermal bond exists between the solar cells and the receiver tube. Cooler propylene glycol is pumped through the receiver tube such that it flows in contact with the back wall of the receiver tube to which the HCPV solar cells are mounted. In cooling the solar cells, the propylene glycol is heated to a higher temperature and the thermal energy is readily available for other thermal processes. The most significant use of the thermal energy from the present invention will be to drive an ammonia absorption air conditioning system. When air-conditioning demand is at a maximum, the available solar energy is also at a maximum.

Different configurations of the receiver assemble can be used. For instance, It may be or become possible to manufacture curved HCPV solar cells to fit on a round tubular receiver tube.

In another embodiment of this device the incoming solar radiation is concentrated and focused onto a thermal absorber pipe assembly as described below:

A black absorber pipe is positioned coaxially within a larger diameter clear glass process pipe. This glass pipe is highly transmissive to solar radiation and also has the capability of containing a fluid at pressures as high as 100 psig and temperatures over 400° F.

Propylene glycol or some other heat transfer fluid is pumped through the annulus between the glass pipe and the smaller black absorber pipe. The heat transfer fluid is thus flowing in direct contact with the absorbing surface effecting very efficient heat transfer into the fluid to be heated.

About 90% to 95% of incident solar radiation is reflected, concentrated, and focused by the conical concentrator onto the outer wall of the glass pipe. About 90% of this radiation transmits through the wall of the glass pipe and thence through the propylene glycol stream before striking and being absorbed by the black surface of the absorber pipe and converted to heat. So, in this embodiment, about 80% of incident solar radiation is absorbed into the fluid to be heated.

This embodiment can provide home air conditioning and heating, hot water, distilled water, swimming pool heating, etc. This represents about ¾'s of a home's energy requirement.

Both of the embodiments of the present invention are supported at the top of a pedestal support column by three hydraulic cylinders. The arrangement of the three hydraulic cylinders is such that the collector may be aimed at the sun wherever the sun is in the sky. Solar tracking of this collector is easily automated. The support pedestal comprises a vertically mounted support column which is anchored at its bottom end to a suitable foundation. Three collector support arms extend horizontally outward from the top of the vertical support column at 120 degree equal intervals.

A hydraulic cylinder trunnion support bearing is pivotally mounted on each the three collector support arms. This mechanism allows additional rotational freedom to accommodate solar tracking. Using three hydraulic cylinders with this additional rotational freedom makes it possible for the three hydraulic cylinders to continually position the solar collector towards the sun. Rotation of the bearings is constrained to limit their rotations only within the bounds of the suns location. Also, for stability, the hydraulic cylinders are not permitted to pivot inward towards the support column.

The hydraulic cylinder rod end clevises of each of the three hydraulic cylinders are pivotally attached to the three collector support arm bearings. The support arm bearings are free to rotate about the axis of the collector support arms. The additional degrees of rotational freedom are necessary in this hydraulic tracking system to accommodate rotation at each bearings during extension or retraction of the three cylinder rods.

The opposing nature of the hydraulic positioning cylinders gives the assembly structural resistance to lateral wind loads. The collector will always be put in stow position with all three cylinders fully retracted whenever wind speeds exceed a certain velocity. In stow position all three of the hydraulic positioning cylinders are fully retracted and stresses on the cylinder rods are minimal. In addition, the streamlined shape of the collector profile presents greatly reduced wind stresses. Because of its aerodynamically streamlined shape, this collector can withstand high wind speed. This is very important for areas around the Gulf Coast, like Houston, Galveston etc.

The three hydraulic positioning cylinders can be controlled by electronic circuitry which uses photocells that change resistance when in the shade or when in sunlight. Three opposing sets of photocells are mounted at a distance beneath the umbrella structure of the solar collector. A very slight deviation of the Sun's position will cause a cell or cells to be in the shade and the electronic circuitry will open or close the appropriate two-way solenoid valves to cause the three hydraulic positioning cylinders to bring the shaded cells back into sunlight and thus maintain the collector facing the sun.

### SUMMARY OF DRAWINGS

FIG. 1 illustrates a perspective view of the solar collector and the support pedestal. Included in the illustration are the conical shaped reflecting concentrator, the absorber pipe assembly, and the three hydraulic positioning cylinders and the bearing assemblies.

FIG. 2 is a detailed perspective illustration of the solar collector support showing attachment of the three cone support arms to the lower cone support ring. FIG. 2 also illustrates the placement of the absorber pipe assembly at the focus of the conical concentrator. FIG. 2 also illustrates the mounting of the three hydraulic cylinder trunnion support bearings onto the collector support arms. FIG. 2 also illustrates the mounting of the conical reflectors three support arms to the rod devises of the hydraulic positioning cylinders.

FIG. 3 is an elevation view of the absorber pipe assembly. Illustrated are the first outer Pyrex glass process pipe and the inner second black metal absorber pipe. An embodiment of the fluid circulation path is also illustrated.

FIG. 4 is a perspective view of the solar collector support and maneuvering mechanism. FIG. 4 illustrates the rotational freedom of the hydraulic cylinder trunnion support bearings and the cone support arm bearings. This rotational freedom is required to accommodate rotation of the bearing assemblies during extension or retraction of the three hydraulic cylinders.

FIG. 5 illustrates a perspective view illustrating the mounting of the hydraulic cylinder trunnions onto the trunnion support bearings and the mounting of the bearing & cylinder assembly onto the collector support arms at the top of the support pedestal.

FIG. 6 is an exploded view showing the assembly of the hydraulic cylinder trunnion support bearings. FIG. 6 shows how the trunnion support bearing are mounted onto the collector support arms. FIG. 6 also illustrate the installation of the hydraulic positioning cylinders onto the trunnion support bearings.

FIG. 7 is an elevation view showing the mounting of the conical concentrator cone support arm onto the cone support arm bearings. FIG. 7 also illustrates the attachment of the cone support arm bearings onto the positioning cylinders rod end clevis.

FIG. 8 illustrates an exploded view of the cone support bearing attached to the cone support arm and the clevis pin bracket.

FIG. 9 illustrates a dissembled view of the absorber pipe assembly.

FIG. 10 is a section view of the cone base cylinder showing the flow path for the pressurized fluid to be heated.

FIG. 11 illustrates the collector base, pedestal support arms and the lower cone support ring.

FIG. 12 is a side elevation view of the cone structure including the reflective collector, upper umbrella, cap and support pedestal (collector base).

FIG. 13 illustrates the attachment of cone umbrella support ribs to the upper structural reinforcing ring of the cone.

FIG. 14 illustrates the top of the cone support pedestal with the three pedestal support arms.

FIG. 15 illustrates how the use of a multi-segmented conical concentrator can achieve very high solar concentrations.

FIG. 16 illustrates the placement on the concentrated photovoltaic cells and star reflecting concentrator at the focal line of the cone.

FIG. 17 shows a hydraulic diagram for the tracking system.

FIG. 18 is a side view of the solar collector with the cone (umbrella) not shown. FIG. 18 illustrates the degree of accuracy of the solar tracking mechanism. FIG. 18 shows how a very slight movement of the sun results in the shading of one or more of the tracking photocells and causes the hydraulic tracker to extend or retract the positioning cylinders as needed to maintain focus on the sun.

### DETAILED DESCRIPTION OF DISCLOSURE

The device includes a solar collector moveably mounted on a support pedestal. The support pedestal may be attached to a concrete foundation on the ground. Other mounting configurations may be utilized.

An inverted truncated conical reflecting surface concentrates and focuses about 90%-95% of the incident solar radiation onto an absorber pipe assembly.

In one embodiment, the absorber pipe assembly consists of a black absorber pipe placed coaxially within a clear glass process pipe. This clear glass process pipe is highly transmissive to solar radiation and also has the capability of containing a fluid under pressures up to 100 psig and temperatures over 400° F.

In operation a heat transfer fluid like Propylene Glycol is pumped through the annulus between the black pipe and the clear glass pipe The heat is transferred away from the absorber pipe assembly by means of the fluid.

About 90% of the incoming radiant solar energy is concentrated and focused onto the outer clear glass wall of the outer glass process pipe. About 90% of this concentrated solar radiation travels through the transparent wall of the glass pipe and enters into the fluid which is flowing in the annulus between the glass pipe and the black absorber pipe. This radiant energy is partially absorbed by the fluid before reaching the black absorbing surface. At the black absorbing surface the radiant energy is converted to thermal energy. The thermal energy is almost totally absorbed into the fluid to be heated. The circulating fluid is flowing under pressure in direct contact with the hottest portion of absorber pipe assembly, the black absorbing surface. This results in approximately 80% of the incoming solar radiation being converted to heat that is absorbed into the fluid to be heated.

Approximately 10% of the available solar energy is lost because of imperfect reflection on the reflecting surface. Another 10% of energy is lost due to imperfect transmission through the glass pipe. The only other energy lost from the collector is due to convective and radiant heat transfer to the ambient from the hot outside surface of the glass pipe. Since the outside surface of the glass pipe is much cooler than a typical absorber pipe (such as the absorber pipe in a parabolic trough collector) the energy lost to the ambient environment is much less.

The only geometric shape that focuses solar radiation equally around the periphery of a linear absorber is an inverted truncated cone. This conical shaped collector is easily fabricated with a high degree of precision from relatively inexpensive materials. The collector can be fabricated from thin gauge steel sheet to which a solar reflective film is bonded. Materials having solar reflectance as high as 95% are available.

Further, the aerodynamic shape of the collector illustrated in this disclosure greatly reduces wind forces on the collector. It is possible for this streamlined shape to withstand very high wind speeds.

The collector is moveably held by a support pedestal. This moveable connection will be explained. Radially attached proximate to the top of the support pedestal are three collector pedestal support arms. These support arms may be welded to the support pedestal. Each arm is spaced radially 120° around the periphery of the support pedestal. Each arm supports hydraulic positioning cylinders which support and move the collector to track the sun.

An electronic control system causes two-way solenoid valves to open or close as needed to individually extend or retract these cylinders so that the collector always faces the sun.

One function of the collector pedestal support arms and attached components described herein below is to maneuver the solar collector in a position of maximum exposure to the sun. This mechanism is referred herein as a “collector tracking mechanism”.

A first group of bearings, the cylinder trunnion support bearings pivotally mount the hydraulic cylinder trunnions to each of the three collector support arms at the support pedestal. These cylinder trunnion support bearings are given the rotational freedom required for solar tracking. These three bearing assemblies provide two degrees of rotation freedom for the positioning cylinders mount on each of the three pedestal radial support arms. Spring constraints control the rotation of the cylinders towards the support pedestal.

A second group of bearing assemblies, the cone support arm bearings, connect the piston cylinder rod end devises to the three cone support arms. These bearings provide two degrees of rotational freedom at the connection between the cone support arm and the cylinder rod end clevis. These three bearings are split sleeve bearings. The three cone support arm bearings are installed around the outside surface of the three cone support arm bearings.

In one embodiment, illustrated in FIG. 4, a trunnion support bearing 11 rotates 21 about the axis of the collector pedestal support arm 19. A hydraulic cylinder 10 rotates 22 about the center of the trunnion support 20. The piston cylinder rod 23 rotates 24 about the axis 10 of the cylinder. The cone support arm bearing assembly (comprising the support arm bearing 9 and piston rod end clevis pin 26) rotates 27 about the rod end clevis pin 26 at the end of the piston cylinder rod 23. The cone support arm 7 rotates 25 inside the cone support arm bearing 9. A spring can constraint 11a prevents the hydraulic cylinders from pivoting inward towards the pedestal. This spring can constraint 11a is structurally attacked to the trunnion support bearing 11 by structural member 11b.

It should be noted that other means of solar tracking can be used.

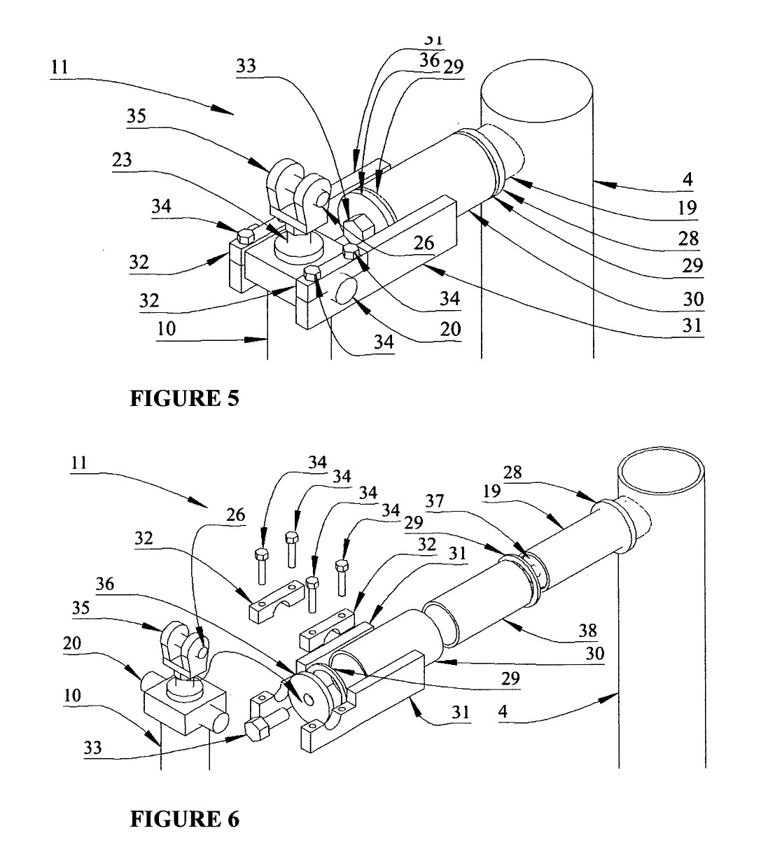

FIG. 5 provides a simplified illustration of the collector support column 4 and the collector pedestal support arm 19, i.e., the cone support arm is not illustrated.

FIG. 6 illustrates the additional components from FIG. 5 but illustrated in an exploded format. FIG. 6 illustrates an embodiment of the collector support column 4 with an attached horizontal collector pedestal support arm 19. Also illustrated is a steel thrust plate 28 attached to the collector pedestal support arm. A bronze (or equivalent) thrust bearing 29 is installed in contact with thrust plate 28. A bronze sleeve bearing (cylindrical shaped) 38 is mounted over the pedestal support arm to touch the thrust bearing. In the illustrated embodiment, two bottom halves 31 of the trunnion support bearing are welded to the outside of steel bearings outside shell 30. This assembly of the bearing shell 30 and the bottom trunnion support bearing halves 31 is slid over the sleeve bearing 38 to touch the thrust washer 29. Another bronze thrust bearing washer 29 is positioned around the end of collector support arms 19. A thrust plate 36 is then bolted to plate 37 with bolt 33. Plate 37 is welded to the inside of the end of the pedestal support arm 19. Plate 37 is drilled and tapped for a bolt 33. This completed assembly rotates about the axis of the pedestal support arm 19.

The hydraulic positioning cylinder 10 is placed so that the cylinder trunnions 20 rest in the bottom halves 31 of the trunnion support bearings 11. The two top halves 32 of the trunnion support bearing 11 are then bolted to the bottom halves 31 of the trunnion support bearing 11 with bolts 34. The bottom halves 31 of the trunnion support bearings are drilled and tapped for the bolts 34. It will be appreciated that hydraulic positioning cylinders 10 are pivotally attached the three cone arm support bearings with rod end clevis 35 and clevis pin 26 extendible from the hydraulic cylinder 10. Extension of the piston cylinder rod from the hydraulic positioning cylinder 10 pushes the clevis bearing upward, causing the collector pedestal support arm bearing (item 9 in FIG. 4) to be moved, which in turn moves the cone support arm (item 7 in FIG. 4). The cone support arm 7 is attached to the lower cone support ring 8. Several different structural designs are possible for the cone structure. Movement of the collector pedestal support arm, initiated by movement of the piston within the hydraulic cylinder, causes the lower cone support ring to move. This moves the entire solar collector.

The illustrated embodiment contains 3 pedestal support arms each containing the above described moving mechanism. In one embodiment, one of the three pedestal support arms is oriented in the North direction. Extension of the North oriented piston cylinder causes the Northern edge of the lower cone support ring to be raised thus elevating the collector to face South. Similarly the other two cylinders raise the collector to face either East or West. Coordinated operation of the piston cylinders at the ends of each pedestal support arm allows the solar collector to be pointed in any direction. To achieve the required stability constraints like the spring can 11a shown in FIG. 4 are used as needed. Also, at least one of the three hydraulic positioning cylinders will and must always be in the fully retracted position.

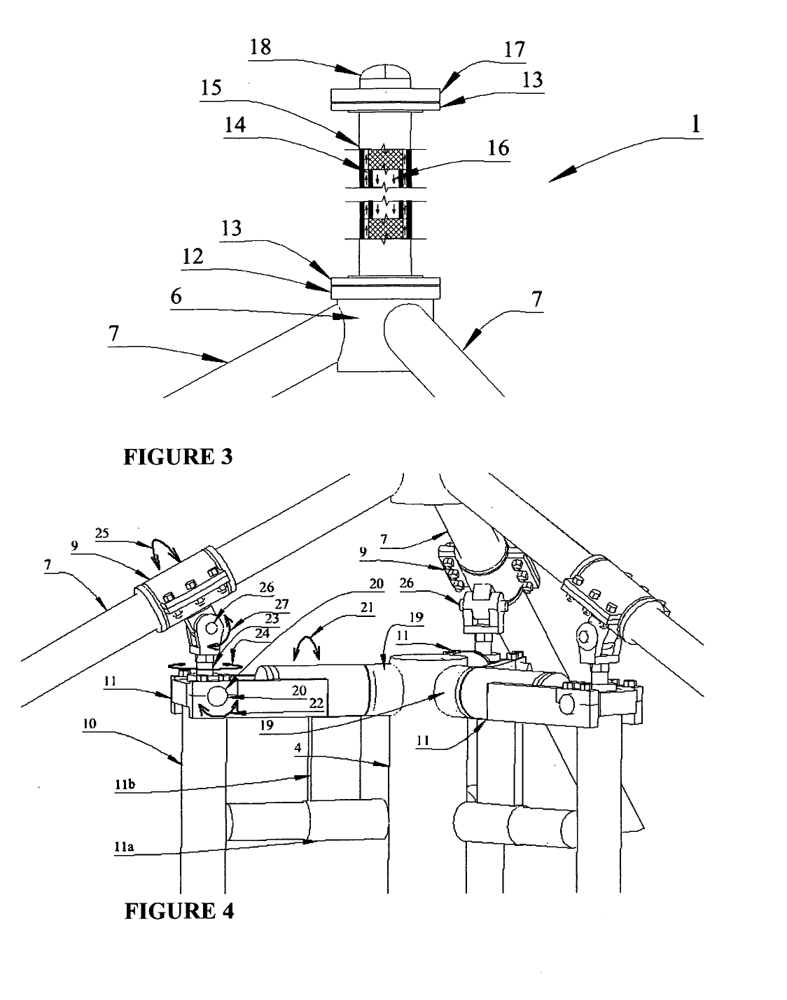

Also disclosed herein is the absorber pipe assembly. This component is illustrated in FIG. 3. The absorber pipe assembly is mounted to the collector base 6. The collector base 6 is at the juncture of the three cone support arms 7. The absorber pipe assembly 1 sits atop the collector base 6. The absorber pipe assembly is positioned within the collector cone at its focal line to receive the concentrated reflected sunlight. The absorber pipe assembly is a dual wall component through which fluids may be pumped. The absorber pipe assembly comprises an outer transparent cylinder. The cylinder may be glass, Plexiglas or other material. A second inner cylinder is comprised of black metal or other similar material that possesses good heat absorption and heat transfer properties. The second cylinder is heated by the focused solar light and the heat is transferred to the fluid circulating under pressure. The second inner black pipe is an excellent heat absorber. Since the fluid flows in direct contact with the hot black absorbing surface, a maximum possible efficiency in the transfer of thermal energy to the fluid is achieved. This heat can be pumped from the solar collector to power other devices. In the embodiment illustrated, propylene glycol is the circulated fluid.

FIG. 3 shows an elevation view of the absorber pipe assembly. A section in the middle shows the fluid 16 flowing through the annulus between the clear glass process pipe 15 and the black absorber pipe 14. The fluid is flowing in direct contact with the black absorbing surface. The absorber pipe assembly consists of a black surfaced steel pipe 14 which is enclosed within a larger diameter transparent glass process pipe 15. An example of this type of glass is Pyrex (or equivalent) glass process pipe. A pipe flange 12 is welded to the top of the collector base 6. Steel absorber pipe 14 may be welded, bolted or similarly attached to the pipe flange 12. The larger diameter glass pipe 15 slips over the black pipe 14 and is fastened to the pipe flange 12 with a heat resistant pipe flange 13. A pipe cap 18 is welded to a slip-on pipe flange 17. This pipe cap 18 and pipe flange 17 assembly is slipped over the top of black pipe 14 and is fastened to the top of the glass pipe 15 with heat resistant glass flange 13. The fluid may move through tubes to heat exchangers or other devices. The re-circulated fluid may be collected in a reservoir container.

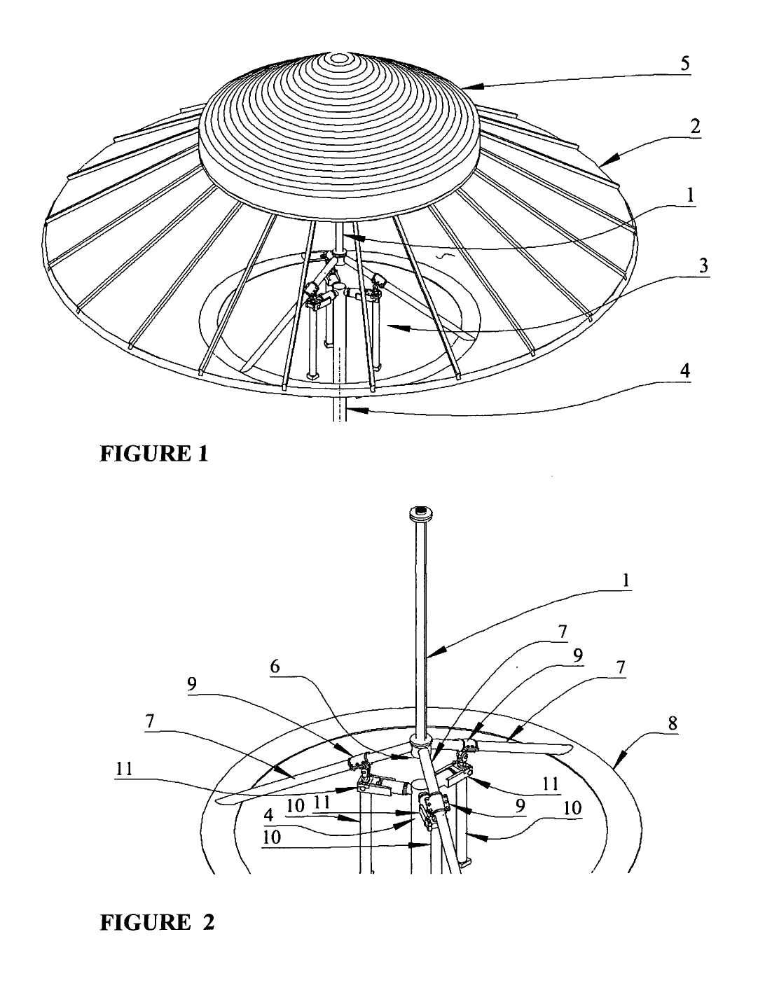

FIG. 1 illustrates the collector tracking mechanism 3. Also illustrated is the support pedestal 4, the absorber pipe assembly 1, the conical reflector 2, and the umbrella 5. HCPV solar cell array's like those made by Amonix may be mounted onto the top of the umbrella. This is a solar tracking area and it should be utilized. Ammonix uses Fresnel lenses to concentrate sunlight onto individual HCPV solar cells. In Ammonix systems, the cells are air cooled, i.e. thermal energy is discarded to ambient.

FIG. 2 illustrates the absorber pipe assembly 1, the pedestal support 4, three hydraulic cylinders 10, and cone support arms 7 attached to the lower cone support ring 8. Also illustrated are three trunnion bearings 11, cone support arm bearings 9, and collector base 6. The absorber pipe assembly is mounted on the collector base 6. In the embodiment illustrated, the three cone support arms extend radially around the periphery of the collector base at 120 degree intervals and at a 30 degree downward slope to the lower cone support ring. The cone support arms 7 are attached to the lower cone support ring 8. The movement and rotation of these components have already been described.

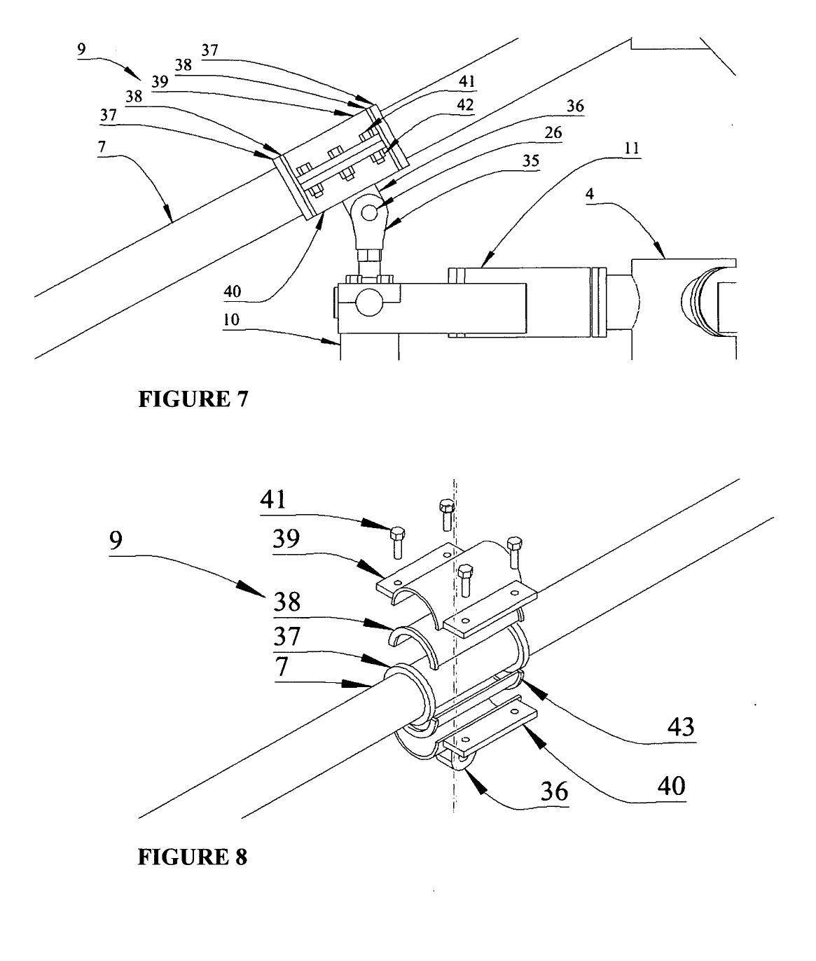

FIG. 7 illustrates the cone support arm bearing 9 of the cone support arm 7 co-joined to the ends of each of the three extendible hydraulic cylinder rods with three clevis bearing assemblies which includes a rod end clevis 35, a clevis bracket 36 and clevis pin 26 at the upper ends of the cylinder rods. It should be noted that the weight of the collector is low. The hydraulic cylinders are very lightly loaded. The bearing assemblies 9 and 11 are also very lightly loaded. Also, the rotational speeds are very low. Simple bronze sleeve bearings and thrust bearings are adequate. It is expected that the life expectancy of the bearings will be very long and maintenance costs will be minimal.

FIG. 8 illustrates the collector support arm bearing 9 in an exploded view. The bearing shell halves 39 and 40 are illustrated along with their fastening bolts 41. The bearing allows rotational movement of the collector support arm bearing 9 about the axis of cone support arm 7. The cone support arm bearings are supported at the rod end clevis 35 of tracking cylinder 10. The clevis bracket 36 is welded to the bottom steel shell 40 of bearing 9. Clevis bracket 36 is pivotally connected to the rod end clevis 35 of tracking cylinder 10 with pivot pin 26. Bronze bearings 38 and 43 are the two halves of a flanged split bronze sleeve bearings. In assembly, the bottom of the split flanged bronze bearing 43 is placed inside the bottom steel shell 40. The combination of the bottom steel shell 40 and bottom bearing half 43 are between the two thrust plates 37 attached to the cone support arm 7. The upper bronze bearings 38 are then placed over the cone support arm 7 between the two thrust plates 37. Then the upper bearing shell 39 is positioned over the upper bearing 38 and bolted to the bottom steel shell 40 with bolts 41 and nuts 42.

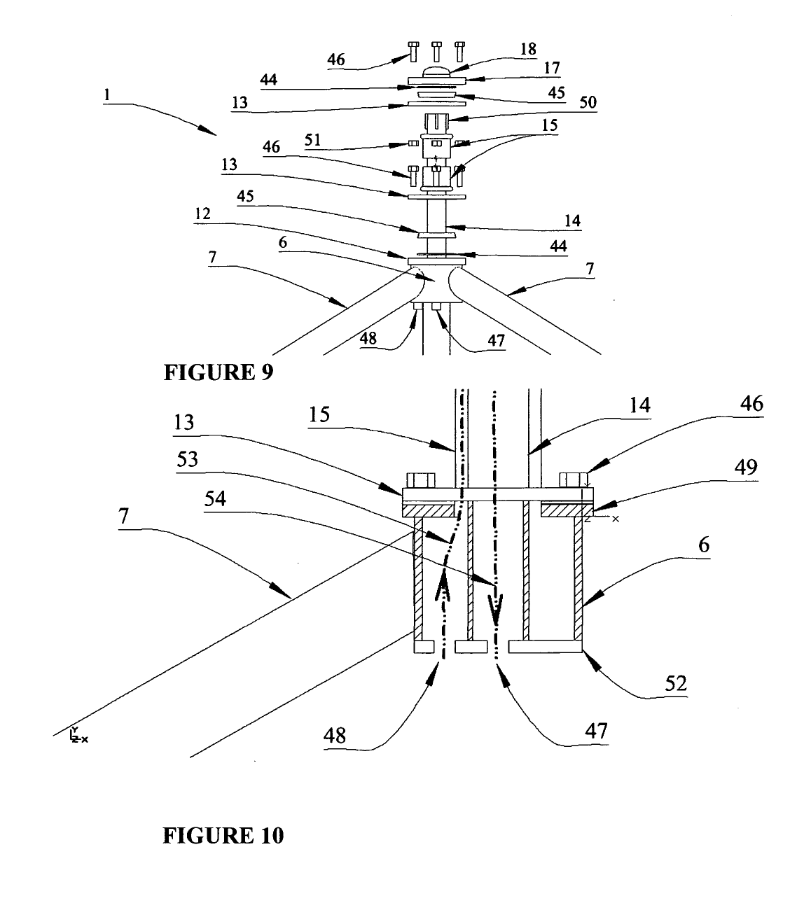

FIG. 9 illustrates a detail of the absorber pipe assembly 1. The steel absorber pipe 14 is welded, bolted or similarly attached to the bottom plate 52 inside the collector base 6. This absorber pipe 14 is coated with a selective black surface. A base plate 12 having the same diameter and bolt pattern as a 150 Ib slip-on pipe flange is welded to the top of the cone base cylinder 6. A heat resistant glass gasket 44 is installed over the black pipe 14 against the face of flange 12. The heat resistant glass process pipe 15 is slipped over the smaller diameter absorber pipe 14 and insert adapter 45 is installed around the conical ends of the glass pipe. A heat resistant glass flange 13 is the installed over the glass pipe and fastened to the base flange 12 with bolts 46. Four lengths of steel square bar 50 are welded to the top outside of the black absorber pipe 14 at 90° intervals. These bars serve to guide the top of the black absorber pipe 14 inside the pipe cap 18 and the difference in thermal expansion between glass and steel is thus accommodated. The outside diameter of the steel pipe 14 and square bars 50 are slightly smaller than the inside diameter of the glass pipe 15 and the pipe cap 18. Pipe cap 18 is the same pipe diameter as the glass pipe 15. With the glass pipe 15 connected at the base plate 12 a heat resistant glass flange 13, heat resistant glass gasket 44 and heat resistant glass insert adapter 45 are positioned at the top of the heat resistant glass pipe 15. The welded assembly of the slip-on flange 17 and pipe cap 18 is slipped over the outside of the steel bars 50 at the top of the steel pipe 14 to contact the top bead of the heat resistant glass pipe 15. The 150 Ib pipe flange 17 is then bolted to the heat resistant glass flange 13 using bolts 46 and nuts 51. Guiding this flanged assembly at the top of the absorber pipe assembly 1 protects the glass pipe 15 from stresses due to the difference in thermal expansion between glass and steel. The steel guides 50 utilize part of the area of the annulus between the top of the steel pipe and the inside of the pipe cap. The remainder of this annulus is open for the flow of the fluid to be heated 16 which has traveled upward in the annulus between the glass pipe 15 and the steel pipe 14. The fluid to be heated enters the top of the black absorber pipe 14 inside the pipe cap 18 and travels downward through the center of the black pipe 14 to exit the collector at a threaded pipe connection 47 at the bottom of the cone base cylinder 6. It should be noted that fluid flow the absorber pipe assembly can also be in the reverse direction.

FIG. 10 is a section view of the cone base cylinder 6 showing the flow path for the fluid to be heated 16. The bottom plate 52 of the cone base cylinder 6 is drilled and tapped for pipe threaded connections 47 and 48. The steel absorber pipe 14 is welded to the bottom plate 52. The bottom plate 52 may be welded or similarly attached to the cone base cylinder 6. The fluid to be heated 16 enters the absorber at the threaded connection 48 and flows upward 53 through the annulus between the black pipe 14 and the glass pipe 15. As shown in FIG. 9 the fluid 16 enters into the top of the black pipe 14. The fluid 16 then flows downward through the steel pipe 14 and leaves the absorber pipe assembly 1 through threaded connection 47 in the center of the bottom plate 52.

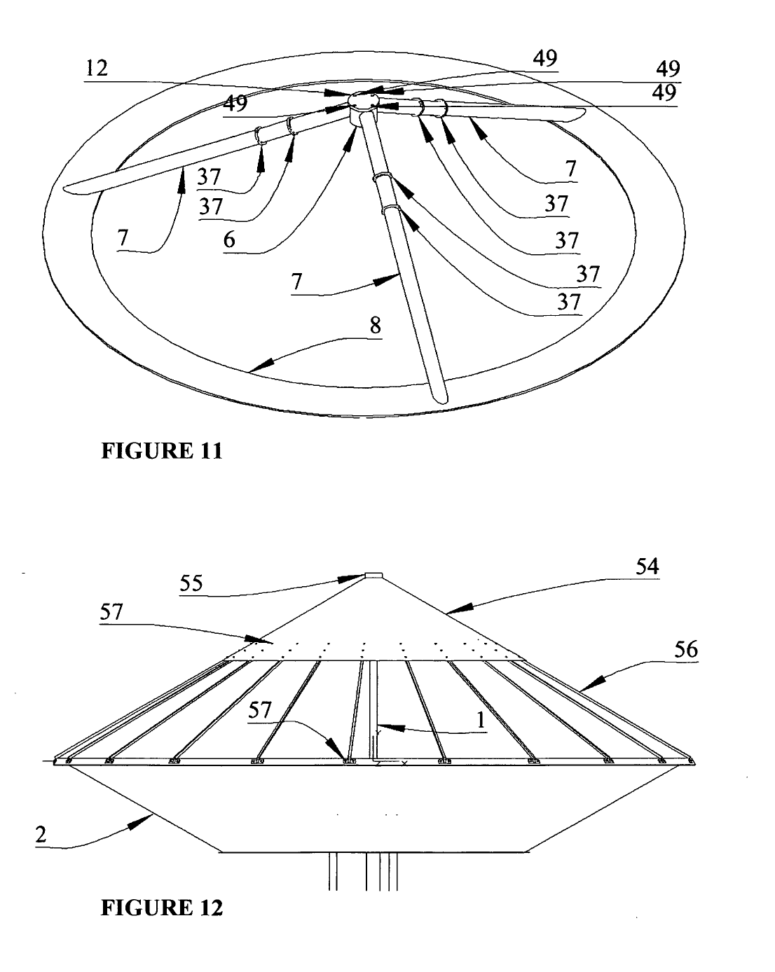

FIG. 11 shows an isometric view of the cone support structure. The cone support arms 7 are welded at their lower ends to the cone support ring 8. The cone support arms 7 are welded to the collector base cylinder 6 at their upper ends. Flange plate 12 is welded to the top of cone base cylinder 6. Flange Plate 12 supports the absorber pipe assembly 1. Two thrust plates 37 positioned on each of the cone support arms 7. FIG. 7 and FIG. 8 show how the cone support arm bearings 9 are installed between these bearings.

It should be noted that several different cone structural support means may also be utilized.

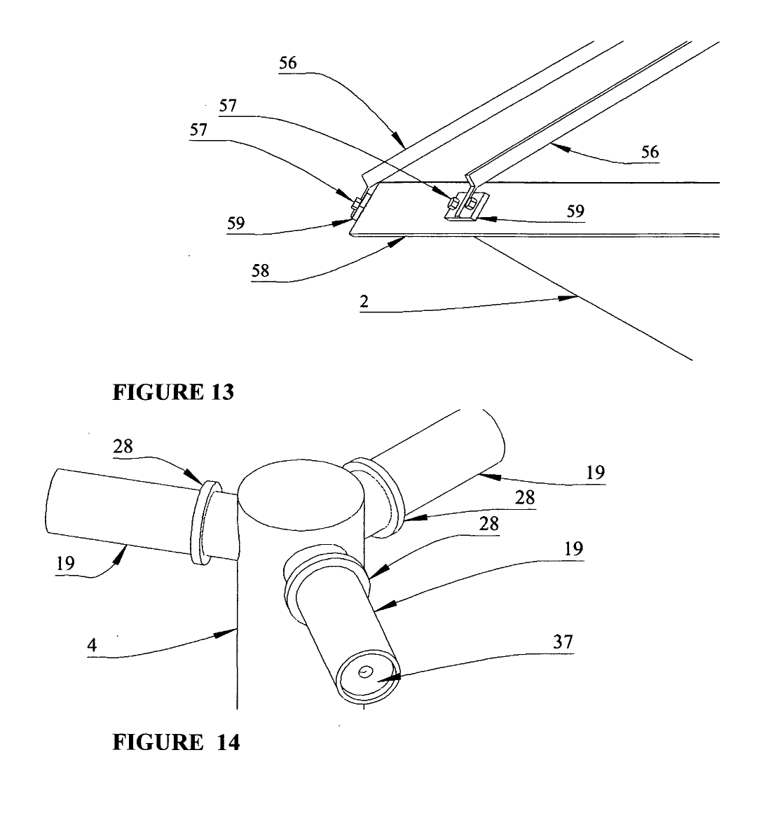

FIG. 12 shows a side view of the collector in stow position. This view shows an upper umbrella 54 and cone ribs 56. The umbrella 54 is made from steel sheet and is fastened to the cone ribs 56. The cone ribs 56 can bolted or welded to the upper cone ring and the absorber pipe guide 55 which is positioned at the top of the cone umbrella (See FIG. 13.) This absorber pipe guide 55 accommodates the difference in thermal expansion between glass and steel.

FIG. 13 shows a side view of the bolted connection 57 of cone ribs 56 to the upper cone ring 58. Bolting plate 59 may be welded or bolted to the end of cone rib 56. The cone umbrella 54 serves several purposes. The cone umbrella 54 provides structural support for the cone 2, including reinforcement and alignment of the top cone rim. The umbrella also presents an area of solar collection which is in the center of the reflecting cone. One embodiment would include mounting a concentrating photovoltaic solar cell array 5 on top of the cone umbrella 54 as shown in FIG. 1. The cone umbrella 54 serves to protect the absorber pipe assembly 1. The top of the umbrella 54 also serves as a structural mount for a pipe guide/support for the top of the absorber pipe 1.

Alternative structural means may also be utilized.

FIG. 14 shows an isometric view of the top of the collector support pedestal 4. Pedestal support arms 19 are welded, bolted or similarly attached to the circumference of the pipe column 4. Thrust plates 28 are mounted to the pedestal support arms 19. Steel plates 37 may be welded, bolted or similarly attached inside the pedestal support arm 19. Plates 37 are drilled and tapped for bolts 33 as shown in FIG. 6.

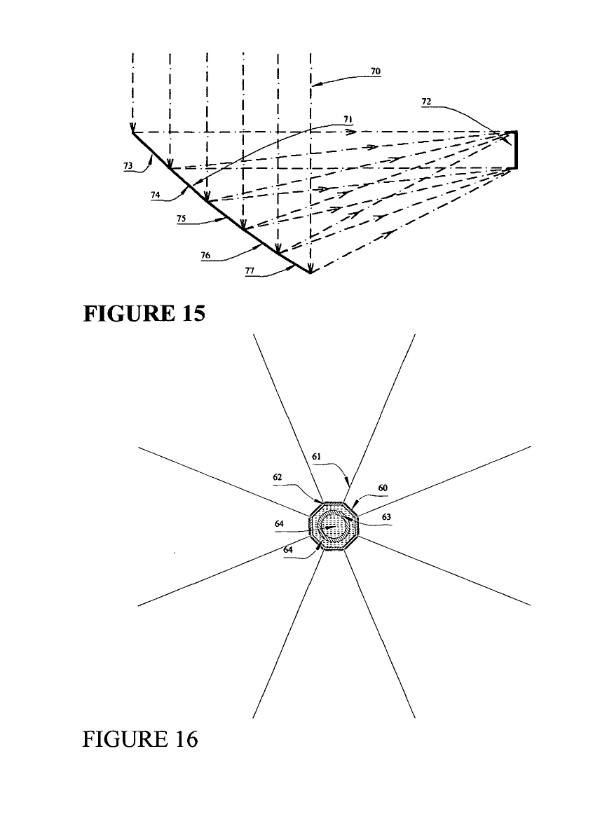

FIG. 15 is a section view showing how incoming solar radiation 70 is reflected, concentrated and focused by an inverted multi-segmented conical reflecting concentrator 71 onto a linear receiver 62 which is comprised of a cylindrical array of High Concentration PhotoVoltaic, HCPV, solar cells 60 mounted onto the flat sides of an octagonal receiver tube. It can be shown that the conical concentrator concentrates solar radiation equally around the periphery of the cylindrical HCPV solar cell array. The top segment 73 of the collector is at a 45° angle and solar rays are reflected horizontally relative to the plane of the top of the top of cone segment 73. The Receiver assembly is positioned along the linear central focus of the cone segment. The next cone segment 74 of the conical concentrator has a top diameter set equal to the bottom diameter the top cone segment 73. The cone angle for cone segment 74 is such that the rays of radiant energy hitting the top of segment 74 are reflected onto the top of the receiver HCPV cylindrical array 72 and solar rays 70 hitting the bottom of segment 74 are reflected onto the bottom of the receiver 72. Likewise, the cone angles and diameters for the next cone segments 75, 76, and 77 are determined and set. Since the concentration of each of the cone segments onto the receiver are additive much higher solar concentrations are possible. Indeed, very high concentrations ratios are necessary for the economical use of the very expensive multi junction HCPV solar cells. Using this multi-segmented cone 71, it is possible to achieve the very high solar concentrations desired.

FIG. 16 is a plan view of the receiver tube showing how the HCPV solar cells 60 are mounted onto an extruded, octagonal receiver tube 62. Reflecting fins 61 placed around the periphery of the receiver tube 62 act to further guide concentrated solar radiation onto the HCPV solar cells. In operation propylene glycol 64 is pumped upwards through a smaller diameter tube 63 which is placed coaxially within the octagonal receiver tube. The cool propylene glycol 64 then flows downward in the annulus between the octagonal HCPV mounting tube 62 and the central smaller diameter tube 63. In acting to cool the HCPV solar cells 60, the propylene glycol 64 is heated. This thermal energy absorbed into the propylene glycol is then available for a variety of thermal processes including ammonia absorption air conditioning.

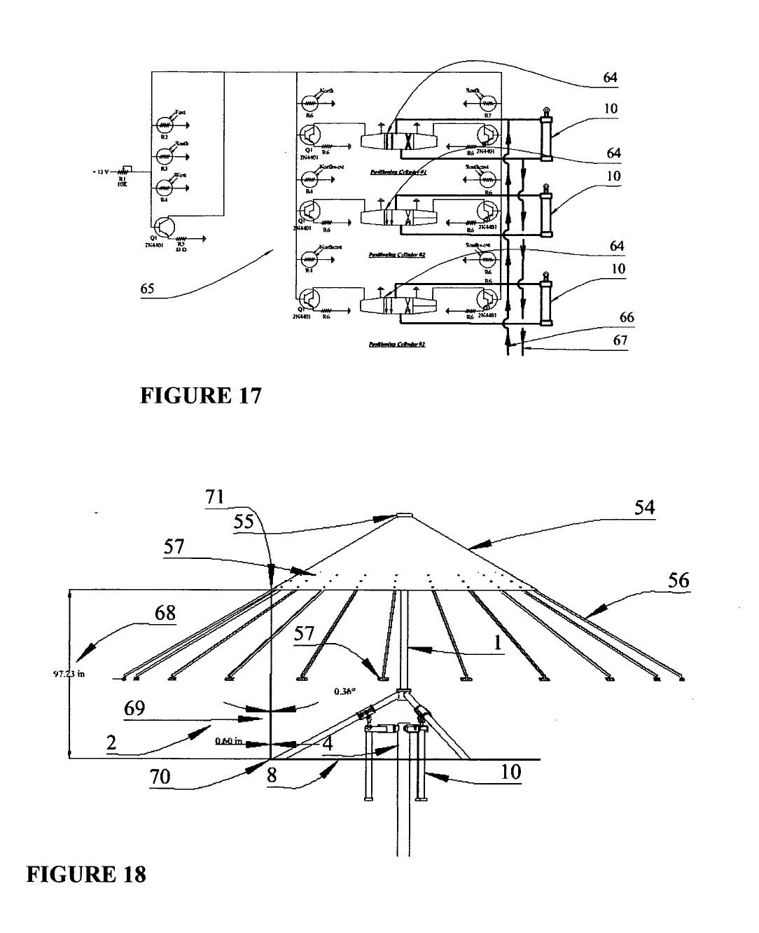

FIG. 17 shows a hydraulic diagram for the tracking system 3. Two way solenoid valves 64 are controlled through electronic circuitry 65 by three sets of opposing photocells. The difference in electrical resistance between a cell 70 in full sunlight and a cell 70 in the shade causes the solenoid valves 64 for each of the hydraulic tracking cylinders 10 to open or close as needed to extend or retract the cylinders. When the collector is pointed directly at the sun all of the six photocells 70 are in full sunlight. As soon as any of the solar cells are in the shade, the collector is moved by the positioning cylinders 10.

In another embodiment, the hydraulic tracking cylinders may be controlled by a CPU embedded with software that directs extension or retraction of each cylinder though the period of sunlight to maximize the absorber pipe assembly to the light. It will be appreciated that the software will account for the latitude and time of year.

FIG. 18 is a shows how the judicious placement of photocells 70 on the cone base plate 8 can be utilized to cause the collector to track the sun with a very high degree of precision. The solar cells 70 are positioned slightly outside the bottom edge of the umbrella 54 such that as long as the collector is facing directly towards the sun all of the photocells are in the sunlight 71. The angular deviation 69 of the sun's position relative to the collector is shown. A very small deviation 69 causes one or two of the cylinders to be shaded. The hydraulic tracking system is actuated and the collector moved to follow the sun. FIG. 18 also shows the attachment of the cone umbrella structure 54 is attached to the reflecting cone 2 with cone support ribs 56. FIG. 18 also shows the attachment of the upper small end other umbrella to absorber pipe guide 55.

1. A multi-segmented conical solar concentrator reflecting surface which concentrates and focuses incoming solar radiation onto a linear receiver tube assembly. Very high concentrations of solar radiation can be achieved such as is necessary for the economical use of HCPV solar cells.

2. A receiver tube assembly which can be placed at the central focal line of the conical concentrator described in claim 1. A cylindrical array of HCPV solar cells is placed around the periphery of a metal tube which has a plurality of flat sides for mounting of the columns of HCPV solar cells. This metal tube may be extruded. It may also be formed and brazed or otherwise sealed using flat metal sheet.

3. A means of actively cooling the solar cells of claim 2 while concurrently heating the fluid which is being used to cool the cells. Maximum amounts of both electrical and thermal energies are thus produced. A smaller diameter tube is placed coaxially within the flat sided receiver tube. Cool heat transfer fluid is pumped through the smaller tube and then flows through the annulus between the flat-sided receiver tube and the smaller tube and acts to remove heat from the cells.

4. An absorber pipe assembly which can be placed at the central focal line of the conical concentrator of claim 1. A transparent glass process is placed coaxially around a smaller black-surfaced absorber pipe. The concentrated solar energy is focused onto the outside glass surface of this absorber pipe assembly. Most of this concentrated energy travels through the glass wall and enters into the annulus between the glass pipe and the smaller black pipe. A heat transfer fluid is caused to flow through the annulus in direct contact with the hot black absorbing surface. A maximum heat transfer efficiency is thus achieved.

5. A hydraulic tracking mechanism which utilizes three vertically oriented hydraulic cylinders mounted around the support pedestal at 120° intervals to control the orientation of the collector/receiver assembly towards the sun. The collector/receiver assembly is supported by these hydraulic cylinders. The extension or retraction of these hydraulic positioning cylinders causes the collector to always face the sun.

6. The mechanism of claim 1 further comprising a plurality of solenoid valves which control retraction or extension of the positioning cylinders to maintain the orientation of the collector towards the sun. Automated means is provided to control the movement of the collector in response to the suns movement across the sky.
